(19) United States
(12) Patent Application Publication
(10) Pub. No.: US 2024/0297515 A1
(43) Pub. Date: Sep. 5, 2024

(54) ELECTROCHEMICAL APPARATUS MANAGEMENT METHOD, SYSTEM, AND CHARGING APPARATUS

(71) Applicant: Dongguan Poweramp Technology Limited, Dongguan (CN)

(72) Inventors: Yarui CHENG, Dongguan (CN); Huixin WANG, Dongguan (CN); Jieming ZHEN, Dongguan (CN); Guoda HE, Dongguan (CN)

(73) Assignee: Dongguan Poweramp Technology Limited, Dongguan (CN)

(21) Appl. No.: 18/647,186

(22) Filed: Apr. 26, 2024

Related U.S. Application Data
(63) Continuation of application No. PCT/CN2021/126428, filed on Oct. 26, 2021.

(51) Int. Cl. H02J 7/00; G01R 31/387; G01R 31/389; H01M 10/42; H01M 10/44; H01M 10/48

(52) U.S. Cl. CPC H02J 7/0048; G01R 31/387; G01R 31/389; H01M 10/425; H01M 10/44; H01M 10/48; H01M 2010/4271; H01M 2010/4278

(57) ABSTRACT

An electrochemical apparatus management method includes: performing a first charge-discharge cycle on an electrochemical apparatus at a charging current; performing an intermittent charging operation on the electrochemical apparatus at a detection current, obtaining data related to the electrochemical apparatus in the intermittent charging operation, and determining a lithium-precipitation state of charge of the electrochemical apparatus based on the data related to the electrochemical apparatus; and in response to the lithium-precipitation state of charge of the electrochemical apparatus being greater than a state-of-charge threshold, performing a second charge-discharge cycle on the electrochemical apparatus at the charging current; or in response to the lithium-precipitation state of charge of the electrochemical apparatus being less than or equal to a state-of-charge threshold, performing a second charge-discharge cycle on the electrochemical apparatus at a target charging current.

### CROSS-REFERENCE TO RELATED APPLICATIONS

This application is a continuation application of International Application No. PCT/CN2021/126428, filed on Oct. 26, 2021, the contents of which is incorporated herein by reference in its entirety.

### TECHNICAL FIELD

This application relates to the field of electrochemical technologies, and specifically, to an electrochemical apparatus management method, a system, an electronic device, and a charging apparatus.

### BACKGROUND

Lithium-ion batteries have many characteristics such as high specific energy density and long cycle life, and are widely used in the field of consumer electronics.

Lithium-ion batteries may experience lithium precipitation during use. When it is detected that batteries have the risk of lithium precipitation, timely measures need to be taken to reduce the risk of lithium precipitation, so as to ensure battery safety.

### SUMMARY

Embodiments of this application are intended to provide an electrochemical apparatus management method, a system, an electronic device, and a charging apparatus, so as to reduce the risk of lithium precipitation during the use of electrochemical apparatuses and improve the safety of electrochemical apparatuses. Specific technical solutions are as follows:

A first aspect of embodiments of this application provides an electrochemical apparatus management method, including: i. performing a first charge-discharge cycle on an electrochemical apparatus at a charging current; ii. performing an intermittent charging operation on the electrochemical apparatus at a detection current, obtaining data related to the electrochemical apparatus in the intermittent charging operation, and determining a lithium-precipitation state of charge of the electrochemical apparatus based on the data related to the electrochemical apparatus; and iii-1. in response to the lithium-precipitation state of charge of the electrochemical apparatus being greater than a state-of-charge threshold, performing a second charge-discharge cycle on the electrochemical apparatus at the charging current; or iii-2. in response to the lithium-precipitation state of charge of the electrochemical apparatus being less than or equal to a state-of-charge threshold, performing a second charge-discharge cycle on the electrochemical apparatus at a target charging current, where the target charging current is less than the charging current.

The technical effects of some embodiments of this application are as follows: The lithium-precipitation state of charge of the electrochemical apparatus is determined based on the data related to the electrochemical apparatus obtained in the intermittent charging operation, and in response to the lithium-precipitation state of charge of the electrochemical apparatus being less than or equal to the state-of-charge threshold, the electrochemical apparatus is charged at a smaller charging current, namely the target charging current. This can reduce the charging current of the electrochemical apparatus to reduce the risk of lithium precipitation, improving the safety of the electrochemical apparatus.

In an embodiment of this application, the electrochemical apparatus management method further includes: after step iii-1, repeating step ii and step iii-1 or iii-2; or after step iii-2, repeating step ii and step iii-1 or iii-2. In this embodiment of this application, in step iii-1, the second charge-discharge cycle can be performed on the electrochemical apparatus at the charging current, thus extending the service life of the electrochemical apparatus; and in step iii-2, the second charge-discharge cycle can be performed on the electrochemical apparatus at a target charging current less than the charging current, thus reducing the risk of lithium precipitation caused by the electrochemical apparatus continuing to operate at the original larger charging current.

In an embodiment of this application, the data related to the electrochemical apparatus includes a state of charge of the electrochemical apparatus and an internal resistance of the electrochemical apparatus; the intermittent charging operation includes multiple charging periods and multiple interruption periods; and the step of obtaining data related to the electrochemical apparatus in the intermittent charging operation, and determining a lithium-precipitation state of charge of the electrochemical apparatus based on the data related to the electrochemical apparatus includes: in the intermittent charging operation, for each of the multiple interruption periods, obtaining a state of charge of the electrochemical apparatus and an internal resistance of the electrochemical apparatus that are corresponding to the interruption periods, and obtaining a first curve based on the obtained multiple states of charge of the electrochemical apparatus and the multiple internal resistances of the electrochemical apparatus corresponding to the multiple states of charge, where the first curve is a mapping curve corresponding to the states of charge and internal resistances of the electrochemical apparatus; and determining the lithium-precipitation state of charge of the electrochemical apparatus based on the first curve.

In an embodiment of this application, the step of determining the lithium-precipitation state of charge of the electrochemical apparatus based on the first curve includes at least one of method 1 or method 2, where method 1 includes: performing a first-order differential on the first curve to obtain a second curve; and determining, as the lithium-precipitation state of charge, a state of charge corresponding to a point at which the second curve first has a negative slope; and method 2 includes: performing a first-order differential on the first curve to obtain a second curve; performing a second-order differential on the second curve to obtain a third curve; and determining, as the lithium-precipitation state of charge, a state of charge corresponding to a point at which the third curve first has a vertical coordinate less than zero.

In an embodiment of this application, the method further includes: determining the target charging current based on a pre-established mapping relationship between charging currents and lithium-precipitation states of charge and at least one of the charging current or the state-of-charge threshold, where the mapping relationship between charging currents and lithium-precipitation states of charge includes at least one charging current and at least one lithium-precipitation state of charge corresponding to the at least one charging current. According to some embodiments of this application, the target charging current is determined based on the mapping relationship between charging currents and lithium-precipitation states of charge, which can reduce the charging current of the electrochemical apparatus to the target charging current to reduce the risk of lithium precipitation, improving the safety of the electrochemical apparatus.

In an embodiment of this application, the step of determining the target charging current based on a pre-established mapping relationship between charging currents and lithium-precipitation states of charge and at least one of the charging current or the state-of-charge threshold includes: determining, as the target charging current, a charging current value in the mapping relationship closest to the charging current; or determining, as a target lithium-precipitation state of charge, a lithium-precipitation state of charge in the mapping relationship that is greater than the state-of-charge threshold and has a smallest difference with the state-of-charge threshold, and determining, as the target charging current, a charging current corresponding to the target lithium-precipitation state. According to some embodiments of this application, the target charging current is determined based on the mapping relationship between charging currents and lithium-precipitation states of charge, which can reduce the charging current of the electrochemical apparatus to the target charging current to reduce the risk of lithium precipitation, improving the safety of the electrochemical apparatus.

In an embodiment of this application, the method further includes: determining the target charging current based on a current ambient temperature, a pre-established mapping relationship between temperatures, charging currents, and lithium-precipitation states of charge, and at least one of the charging current or the state-of-charge threshold, where the mapping relationship between temperatures, charging currents, and lithium-precipitation states of charge includes at least one ambient temperature, at least one charging current, and at least one lithium-precipitation state of charge corresponding to the at least one charging current. According to some embodiments of this application, at different ambient temperatures, the charging current of the electrochemical apparatus can be reduced to the target charging current to reduce the risk of lithium precipitation, improving the safety of the electrochemical apparatus operating at different ambient temperatures.

In an embodiment of this application, the step of determining the target charging current based on a current ambient temperature, a pre-established mapping relationship between temperatures, charging currents and lithium-precipitation states of charge, and at least one of the charging current or the state-of-charge threshold includes: at the current ambient temperature, determining, as the target charging current, a charging current value in the mapping relationship closest to the charging current; or at the current ambient temperature, determining, as a target lithium-precipitation state of charge, a lithium-precipitation state of charge in the mapping relationship that is greater than the state-of-charge threshold and has a smallest difference with the state-of-charge threshold, and determining, as the target charging current, a charging current corresponding to the target lithium-precipitation state. According to some embodiments of this application, at different ambient temperatures, the charging current of the electrochemical apparatus can be reduced to the target charging current to reduce the risk of lithium precipitation, improving the safety of the electrochemical apparatus operating at different ambient temperatures.

In an embodiment of this application, the step of performing an intermittent charging operation on the electrochemical apparatus includes multiple charging cycles, each charging cycle includes a charging period and an interruption period, and during each charging period, the state of charge of the electrochemical apparatus increases by a unit amplitude. According to some embodiments of this application, the lithium-precipitation state of charge of the electrochemical apparatus can be determined based on the intermittent charging operation, reducing the risk of lithium precipitation of the electrochemical apparatus.

In an embodiment of this application, the electrochemical apparatus includes at least one of a lithium iron phosphate, a lithium nickel cobalt manganate, or a lithium cobalt oxide, where in a case that the electrochemical apparatus includes the lithium iron phosphate, the unit amplitude ranges from 0.5% to 10%, and duration of the interruption period ranges from 1 second to 15 seconds; in a case that the electrochemical apparatus includes the lithium nickel cobalt manganate, the unit amplitude ranges from 0.5% to 10%, and duration of the interruption period ranges from 1 second to 30 seconds; and in a case that the electrochemical apparatus includes the lithium cobalt oxide, the unit amplitude ranges from 0.5% to 10%, and duration of the interruption period ranges from 1 second to 30 seconds. According to some embodiments of this application, the intermittent charging operation is performed more targetedly on the electrochemical apparatuses of different systems, so that the lithium-precipitation states of charge of the electrochemical apparatuses of different systems can be obtained more accurately.

In an embodiment of this application, the method satisfies at least one of conditions (a) to (f): (a) the electrochemical apparatus includes the lithium iron phosphate, the electrochemical apparatus is at an ambient temperature of −10° C. to 10° C., the unit amplitude ranges from 0.5% to 10%, and duration of the interruption period ranges from 5 second to 15 seconds; (b) the electrochemical apparatus includes the lithium iron phosphate, the electrochemical apparatus is at an ambient temperature of 10° C. to 45° C., the unit amplitude ranges from 0.5% to 10%, and duration of the interruption period ranges from 1 second to 10 seconds; (c) the electrochemical apparatus includes the lithium nickel cobalt manganate, the electrochemical apparatus is at an ambient temperature of −10° C. to 10° C., the unit amplitude ranges from 0.5% to 10%, and duration of the interruption period ranges from 10 second to 30 seconds; (d) the electrochemical apparatus includes the lithium nickel cobalt manganate, the electrochemical apparatus is at an ambient temperature of 10° C. to 45° C., the unit amplitude ranges from 0.5% to 10%, and duration of the interruption period ranges from 1 second to 10 seconds; (e) the electrochemical apparatus includes the lithium cobalt oxide, the electrochemical apparatus is at an ambient temperature of −10° C. to 10° C., the unit amplitude ranges from 0.5% to 10%, and duration of the interruption period ranges from 15 second to 30 seconds; or (f) the electrochemical apparatus includes the lithium cobalt oxide, the electrochemical apparatus is at an ambient temperature of 10° C. to 45° C., the unit amplitude ranges from 0.5% to 10%, and duration of the interruption period ranges from 1 second to 10 seconds. According to some embodiments of this application, the intermittent charging operation is performed more targetedly on the electrochemical apparatuses at different ambient temperatures, so that the lithium-precipitation states of charge of the electrochemical apparatuses of different systems can be obtained more accurately.

A second aspect of embodiments of this application provides a computer-readable storage medium. The computer-readable storage medium stores a computer program, and when the computer program is executed by a processor, the steps of the method according to any one of the foregoing embodiments are implemented.

A third aspect of embodiments of this application provides a charging apparatus including a processor and a machine-readable storage medium, where the machine-readable storage medium stores machine-executable instructions capable of being executed by the processor, and when the processor executes the machine-executable instructions, the steps of the method according to any one of the foregoing embodiments are implemented.

A fourth aspect of embodiments of this application provides an electrochemical apparatus including a processor and a machine-readable storage medium, where the machine-readable storage medium stores machine-executable instructions capable of being executed by the processor, and when the processor executes the machine-executable instructions, the steps of the method according to any one of the foregoing embodiments are implemented.

A fifth aspect of embodiments of this application provides an electronic device, where the electronic device includes the electrochemical apparatus according to the fourth aspect.

A sixth aspect of embodiments of this application provides a system, where the system includes a charging and discharging apparatus and a state-of-charge analysis apparatus. The charging and discharging apparatus is configured to perform a first charge-discharge cycle on an electrochemical apparatus at a charging current; the state-of-charge analysis apparatus is configured to perform an intermittent charging operation on the electrochemical apparatus at a detection current, obtain data related to the electrochemical apparatus in the intermittent charging operation, and determine a lithium-precipitation state of charge of the electrochemical apparatus based on the data related to the electrochemical apparatus; and the charging and discharging apparatus is further configured to: in response to the lithium-precipitation state of charge of the electrochemical apparatus being greater than a state-of-charge threshold, perform a second charge-discharge cycle on the electrochemical apparatus at the charging current; or in response to the lithium-precipitation state of charge of the electrochemical apparatus being less than or equal to a state-of-charge threshold, perform a second charge-discharge cycle on the electrochemical apparatus at a target charging current, where the target charging current is less than the charging current. Some embodiments of this application can reduce the charging current of the electrochemical apparatus to reduce the risk of lithium precipitation, improving the safety of the electrochemical apparatus.

In an embodiment of this application, the data related to the electrochemical apparatus includes a state of charge of the electrochemical apparatus and an internal resistance of the electrochemical apparatus; the intermittent charging operation includes multiple charging periods and multiple interruption periods; and the state-of-charge analysis apparatus is specifically configured to: in the intermittent charging operation, for each of the multiple interruption periods, obtain a state of charge of the electrochemical apparatus and an internal resistance of the electrochemical apparatus that are corresponding to the interruption periods, and obtain a first curve based on the obtained multiple states of charge of the electrochemical apparatus and the multiple internal resistances of the electrochemical apparatus corresponding to the multiple states of charge, where the first curve is a mapping curve corresponding to the states of charge and internal resistances of the electrochemical apparatus; and determine the lithium-precipitation state of charge of the electrochemical apparatus based on the first curve. Some embodiments of this application reduce the risk of lithium precipitation caused by the electrochemical apparatus continuing to operate at the original larger charging current.

In an embodiment of this application, the state-of-charge analysis apparatus is specifically configured to: perform a first-order differential on the first curve to obtain a second curve; and determine, as the lithium-precipitation state of charge, a state of charge corresponding to a point at which the second curve first has a negative slope; or perform a first-order differential on the first curve to obtain a second curve; perform a second-order differential on the second curve to obtain a third curve; and determine, as the lithium-precipitation state of charge, a state of charge corresponding to a point at which the third curve first has a vertical coordinate less than zero.

In an embodiment of this application, the charging and discharging apparatus is further configured to: determine the target charging current based on a pre-established mapping relationship between charging currents and lithium-precipitation states of charge and at least one of the charging current or the state-of-charge threshold, where the mapping relationship between charging currents and lithium-precipitation states of charge includes at least one charging current and at least one lithium-precipitation state of charge corresponding to the at least one charging current. According to some embodiments of this application, the target charging current is determined based on the mapping relationship between charging currents and lithium-precipitation states of charge, which can reduce the charging current of the electrochemical apparatus to the target charging current to reduce the risk of lithium precipitation, improving the safety of the electrochemical apparatus.

In an embodiment of this application, the charging and discharging apparatus is specifically configured to: determine, as the target charging current, a charging current value in the mapping relationship closest to the charging current; or determine, as a target lithium-precipitation state of charge, a lithium-precipitation state of charge in the mapping relationship that is greater than the state-of-charge threshold and has a smallest difference with the state-of-charge threshold, and determine, as the target charging current, a charging current corresponding to the target lithium-precipitation state. According to some embodiments of this application, the target charging current is determined based on the mapping relationship between charging currents and lithium-precipitation states of charge, which can reduce the charging current of the electrochemical apparatus to the target charging current to reduce the risk of lithium precipitation, improving the safety of the electrochemical apparatus.

In an embodiment of this application, the charging and discharging apparatus is further configured to: determine the target charging current based on a current ambient temperature, a pre-established mapping relationship between temperatures, charging currents, and lithium-precipitation states of charge, and at least one of the charging current or the state-of-charge threshold, where the mapping relationship between temperatures, charging currents, and lithium-precipitation states of charge includes at least one ambient temperature, at least one charging current, and at least one lithium-precipitation state of charge corresponding to the at least one charging current. According to some embodiments of this application, at different ambient temperatures, the charging current of the electrochemical apparatus can be reduced to the target charging current to reduce the risk of lithium precipitation, improving the safety of the electrochemical apparatus operating at different ambient temperatures.

In an embodiment of this application, the charging and discharging apparatus is specifically configured to: at the current ambient temperature, determine, as the target charging current, a charging current value in the mapping relationship closest to the charging current; or at the current ambient temperature, determine, as a target lithium-precipitation state of charge, a lithium-precipitation state of charge in the mapping relationship that is greater than the state-of-charge threshold and has a smallest difference with the state-of-charge threshold, and determine, as the target charging current, a charging current corresponding to the target lithium-precipitation state. According to some embodiments of this application, at different ambient temperatures, the charging current of the electrochemical apparatus can be reduced to the target charging current to reduce the risk of lithium precipitation, improving the safety of the electrochemical apparatus operating at different ambient temperatures.

In an embodiment of this application, the intermittent charging operation includes multiple charging cycles, each charging cycle includes a charging period and an interruption period, and during each charging period, the state of charge of the electrochemical apparatus increases by a unit amplitude. According to some embodiments of this application, the lithium-precipitation state of charge of the electrochemical apparatus can be determined based on the intermittent charging operation, reducing the risk of lithium precipitation of the electrochemical apparatus.

In an embodiment of this application, the electrochemical apparatus includes at least one of lithium iron phosphate, lithium nickel cobalt manganate, or lithium cobalt oxide, wherein in a case that the electrochemical apparatus includes lithium iron phosphate, the unit amplitude ranges from 0.5% to 10%, and duration of the interruption period ranges from 1 second to 15 seconds; in a case that the electrochemical apparatus includes lithium nickel cobalt manganate, the unit amplitude ranges from 0.5% to 10%, and duration of the interruption period ranges from 1 second to 30 seconds; and in a case that the electrochemical apparatus includes lithium cobalt oxide, the unit amplitude ranges from 0.5% to 10%, and duration of the interruption period ranges from 1 second to 30 seconds. According to some embodiments of this application, the intermittent charging operation is performed more targetedly on the electrochemical apparatuses of different systems, so that the lithium-precipitation states of charge of the electrochemical apparatuses of different systems can be obtained more accurately.

In an embodiment of this application, the state-of-charge analysis apparatus is specifically configured for at least one of the following (a) to (f): (a) the electrochemical apparatus includes lithium iron phosphate, the electrochemical apparatus is at an ambient temperature of −10° C. to 10° C., the unit amplitude ranges from 0.5% to 10%, and duration of the interruption period ranges from 5 second to 15 seconds; (b) the electrochemical apparatus includes lithium iron phosphate, the electrochemical apparatus is at an ambient temperature of 10° C. to 45° C., the unit amplitude ranges from 0.5% to 10%, and duration of the interruption period ranges from 1 second to 10 seconds; (c) the electrochemical apparatus includes lithium nickel cobalt manganate, the electrochemical apparatus is at an ambient temperature of −10° C. to 10° C., the unit amplitude ranges from 0.5% to 10%, and duration of the interruption period ranges from 10 second to 30 seconds; (d) the electrochemical apparatus includes lithium nickel cobalt manganate, the electrochemical apparatus is at an ambient temperature of 10° C. to 45° C., the unit amplitude ranges from 0.5% to 10%, and duration of the interruption period ranges from 1 second to 10 seconds; (e) the electrochemical apparatus includes lithium cobalt oxide, the electrochemical apparatus is at an ambient temperature of −10° C. to 10° C., the unit amplitude ranges from 0.5% to 10%, and duration of the interruption period ranges from 15 second to 30 seconds; or (f) the electrochemical apparatus includes lithium cobalt oxide, the electrochemical apparatus is at an ambient temperature of 10° C. to 45° C., the unit amplitude ranges from 0.5% to 10%, and duration of the interruption period ranges from 1 second to 10 seconds. According to some embodiments of this application, the intermittent charging operation is performed more targetedly on the electrochemical apparatuses at different ambient temperatures, so that the lithium-precipitation states of charge of the electrochemical apparatuses of different systems can be obtained more accurately.

According to the electrochemical apparatus management method, system, electronic device, and charging apparatus in some embodiments of this application, the lithium-precipitation state of charge of the electrochemical apparatus is determined based on the data related to the electrochemical apparatus obtained in the intermittent charging operation, and in response to the lithium-precipitation state of charge of the electrochemical apparatus being less than or equal to the state-of-charge threshold, the electrochemical apparatus is charged at a smaller charging current, namely the target charging current. This can reduce the charging current of the electrochemical apparatus to reduce the risk of lithium precipitation, improving the safety of the electrochemical apparatus. Certainly, when any one of the products or methods of this application is implemented, all advantages described above are not necessarily demonstrated simultaneously.

### BRIEF DESCRIPTION OF DRAWINGS

To describe the technical solutions in this application and the prior art more clearly, the following briefly describes the accompanying drawings required for describing the embodiments and the prior art. Apparently, the accompanying drawings in the following description show merely some embodiments of this application.

FIG. 1 is a schematic flowchart of an electrochemical apparatus management method according to an embodiment of this application;

FIG. 2 is a schematic diagram of a first curve according to an embodiment of this application;

FIG. 3 is a schematic diagram of a second curve according to an embodiment of this application;

FIG. 4 is a schematic structural diagram of a system according to an embodiment of this application;

FIG. 5 is a schematic structural diagram of a charging apparatus according to an embodiment of this application; and

FIG. 6 is another schematic structural diagram of a system according to an embodiment of this application.

### DETAILED DESCRIPTION

To make the objectives, technical solutions, and advantages of this application more comprehensible, the following describes this application in detail with reference to accompanying drawings and embodiments. Apparently, the described embodiments are merely some but not all of the embodiments of this application. All other technical solutions obtained by persons of ordinary skill in the art based on some embodiments of this application fall within the protection scope of this application.

It should be noted that in specific embodiments of this application, an example in which a lithium-ion battery is used as an electrochemical apparatus is used to illustrate this application. However, the electrochemical apparatus in this application is not limited to the lithium-ion battery.

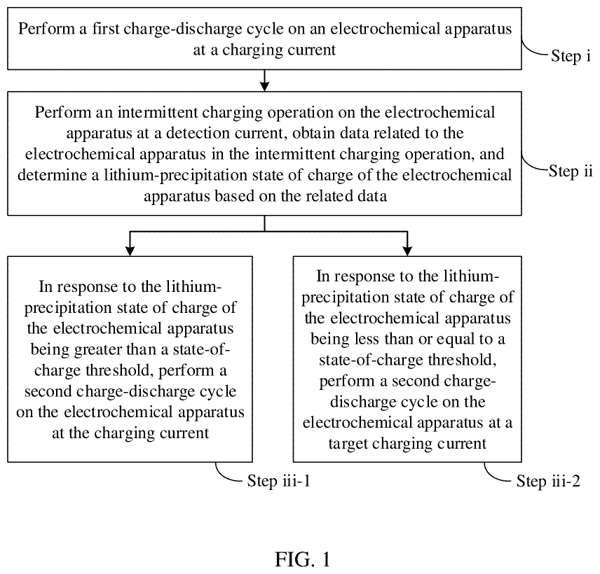

An embodiment of this application provides an electrochemical apparatus management method. As shown in FIG. 1, the method includes the following steps.

Step i. Perform a first charge-discharge cycle on an electrochemical apparatus at a charging current.

The embodiment of this application may be executed by a battery management system. During operation of the electrochemical apparatus, the battery management system can manage the electrochemical apparatus, for example, managing the charging and discharging process of the electrochemical apparatus.

In an embodiment of this application, the battery management system can control a charging current during a charge-discharge cycle of the electrochemical apparatus. For example, during operation of the electrochemical apparatus, a charging and discharging apparatus 401 in the battery management system performs a charge-discharge cycle on the electrochemical apparatus at a charging current. In some embodiments of this application, the charge-discharge cycle may refer to the cyclic process of charging, discharging, and charging of the electrochemical apparatus during operation. In the first charge-discharge cycle, the electrochemical apparatus can be charged at the charging current in its charging stage. In addition, a discharging current in the charge-discharge cycle can be adapted based on the electric device, which is not limited in some embodiments of this application.

A structure of the charging and discharging apparatus is not particularly limited in some embodiments of this application. For example, the charging and discharging apparatus may include a charging and discharging circuit in the field, which is not limited in this application. For example, the charging and discharging circuit may be the charging and discharging circuit 504 shown in FIG. 5. The charging current is not particularly limited in some embodiments of this application, for example, may be any current between 0.1 A and 3 A, such as 0.1 A, 0.2 A, 0.3 A, 0.5 A, 0.7 A, 1 A, 1.5 A, 2 A, 2.5 A OR 3 A.

Step ii. Perform an intermittent charging operation on the electrochemical apparatus at a detection current, obtain data related to the electrochemical apparatus in the intermittent charging operation, and determine a lithium-precipitation state of charge of the electrochemical apparatus based on the data related to the electrochemical apparatus.

In some embodiments of this application, the intermittent charging operation may refer to a process of intermittently charging the electrochemical apparatus. In an embodiment of this application, the intermittent charging operation includes multiple charging periods and multiple interruption periods.

The lithium-precipitation state of charge may refer to a state of charge related to a lithium-precipitation state of the electrochemical apparatus. For example, the state-of-charge analysis apparatus 402 in the battery management system can perform an intermittent charging operation on the electrochemical apparatus. The state-of-charge analysis apparatus is not particularly limited in some embodiments of this application, provided that the intermittent charging operation can be implemented. The state-of-charge analysis apparatus 402 may include, for example, a microcontroller unit (Microcontroller Unit, MCU) in the battery management system (Battery Management System, BMS). In an example, after a first count of first charge-discharge cycles has been performed by the charging and discharging apparatus 401 on the electrochemical apparatus, the state-of-charge analysis apparatus 402 performs, in response to the first charge-discharge cycles having reached the first count, an intermittent charging operation on the electrochemical apparatus at a detection current, performs lithium precipitation detection and analysis on the electrochemical apparatus during the intermittent charging operation, obtain data related to the electrochemical apparatus in the intermittent charging operation, and determine a lithium-precipitation state of charge of the electrochemical apparatus based on the data related to the electrochemical apparatus. The state of charge can be denoted as SOC (State of Charge). The operations of the foregoing process are for illustration purposes only.

The data related to the electrochemical apparatus can be data capable of reflecting the state of the electrochemical apparatus, including but not limited to data such as the charging voltage, charging current, internal resistance, and state of charge of the electrochemical apparatus.

The charging mode in the intermittent charging operation is not particularly limited in some embodiments of this application, provided that the objectives of some embodiments of this application can be achieved. The charging mode may be constant-voltage charging, constant-current charging, constant-current and constant-voltage charging, or segmented constant-current charging.

Step iii-1. In response to the lithium-precipitation state of charge of the electrochemical apparatus being greater than a state-of-charge threshold, perform a second charge-discharge cycle on the electrochemical apparatus at the charging current.

For example, the state-of-charge analysis apparatus 402 performs an intermittent charging operation on the electrochemical apparatus, performs lithium precipitation detection and analysis on the electrochemical apparatus during the intermittent charging operation, and in a case that the lithium precipitation state of charge of the electrochemical apparatus is greater than the state-of-charge threshold, sends a first signal to the charging and discharging apparatus 401. After receiving the first signal, the charging and discharging apparatus 401 performs a second charge-discharge cycle on the electrochemical apparatus at the charging current. The number of second charge-discharge cycles may be less than or equal to the number of first charge-discharge cycles. This is because as cycling of the electrochemical apparatus continues, its lithium precipitation window gradually narrows, that is, lithium precipitation is more likely to occur. Therefore, the number of second charge-discharge cycles is set to be less than that of first charge-discharge cycles, so that lithium precipitation detection and analysis can be performed on the electrochemical apparatus again after the specified number of second charge-discharge cycles has been completed. In an embodiment of this application, for example, the number of first charge-discharge cycles may be 1 to 500, and the number of second charge-discharge cycles may be 1 to 100. The operations of the foregoing process are for illustration purposes only. In addition, the apparatuses and modules in the example of the battery management system in some embodiments of this application are for illustrative purposes only, but not intended to constitute any limitation.

According to some embodiments of this application, the data related to the electrochemical apparatus can be obtained during the intermittent charging operation on the electrochemical apparatus, and the lithium-precipitation state of charge of the electrochemical apparatus can be determined based on such data, so that protective measures can be taken for the electrochemical apparatus subsequently.

The lithium-precipitation state of charge may refer to a state of charge related to a lithium-precipitation state of the electrochemical apparatus. The state-of-charge threshold may be a threshold specified in advance. The state-of-charge threshold may be stored in advance in a storage medium connected to the electrochemical apparatus. The state-of-charge threshold is typically set based on the state of charge corresponding to occurrence of lithium precipitation in an electrochemical apparatus sample of the same system as the electrochemical apparatus. For example, the state-of-charge threshold may be set to a state of charge corresponding to occurrence of lithium precipitation in the electrochemical apparatus sample. For electrochemical apparatuses of different systems, typically different state-of-charge thresholds are set. For the same electrochemical apparatus sample, the states of charge corresponding to occurrence of lithium precipitation are also different under different charging rates and/or ambient temperatures. In some embodiments, the mapping relationship between charging currents and lithium-precipitation states of charge, or the mapping relationship between temperatures, charging currents, and lithium-precipitation states of charge may be set in advance, and the mapping relationship is stored in a storage medium connected to the electrochemical apparatus.

When the lithium-precipitation state of charge is greater than the state-of-charge threshold, it indicates that the electrochemical apparatus has not experienced lithium precipitation yet and therefore can continue operating. Based on this, in some embodiments of this application, the second charge-discharge cycle may be performed on the electrochemical apparatus at the charging current to make the electrochemical apparatus maintain operating. This alleviates the “false killing” problem that the electrochemical apparatus is discarded before its service life is reached.

Step iii-2. In response to the lithium-precipitation state of charge of the electrochemical apparatus being less than or equal to a state-of-charge threshold, perform a second charge-discharge cycle on the electrochemical apparatus at a target charging current.

For example, the state-of-charge analysis apparatus 402 performs an intermittent charging operation on the electrochemical apparatus, performs lithium precipitation detection and analysis on the electrochemical apparatus during the intermittent charging operation, and in a case that the lithium-precipitation state of charge of the electrochemical apparatus is less than or equal to the state-of-charge threshold, sends a second signal to the charging and discharging apparatus 401. After receiving the second signal, the charging and discharging apparatus 401 performs a second charge-discharge cycle on the electrochemical apparatus at a target charging current, where the target charging current is less than the charging current. The operations of the foregoing process are for illustration purposes only. In addition, the apparatuses and modules in the example of the battery management system in some embodiments of this application are for illustrative purposes only, but not intended to constitute any limitation.

The embodiment of this application can reduce the charging current of the electrochemical apparatus when the lithium-precipitation state of charge of the electrochemical apparatus is less than or equal to the state-of-charge threshold. Normally, if the lithium-precipitation state of charge of the electrochemical apparatus is less than or equal to the state-of-charge threshold, it indicates that lithium precipitation tends to occur or has already occurred in the electrochemical apparatus. In this case, reducing the charging current of the electrochemical apparatus can reduce the risk of lithium precipitation caused by the electrochemical apparatus continuing to operate at the original larger charging current, thus improving the use safety of the electrochemical apparatus.

In an embodiment of this application, after step iii-1, step ii and step iii-1 or iii-2 are repeated.

According to some embodiments of this application, after the second charge-discharge cycle is performed on the electrochemical apparatus at the charging current in response to the lithium-precipitation state of charge of the electrochemical apparatus being greater than the state-of-charge threshold, that is, after step iii-1, the intermittent charging operation can be performed on the electrochemical apparatus again, data related to the electrochemical apparatus is obtained in the intermittent charging operation, and the lithium-precipitation state of charge of the electrochemical apparatus is determined based on the data related to the electrochemical apparatus, thus determining the value relationship between the lithium-precipitation state of charge of the electrochemical apparatus and the state-of-charge threshold and then performing step iii-1 or iii-2. In step iii-1, the second charge-discharge cycle can be performed on the electrochemical apparatus at the charging current, thus extending the service life of the electrochemical apparatus; and in step iii-2, the second charge-discharge cycle can be performed on the electrochemical apparatus at a target charging current less than the charging current, thus reducing the risk of lithium precipitation caused by the electrochemical apparatus continuing to operate at the original larger charging current.

In an embodiment of this application, after step iii-2, step ii and step iii-1 or iii-2 are repeated.

According to some embodiments of this application, after the second charge-discharge cycle is performed on the electrochemical apparatus at the target charging current in response to the lithium-precipitation state of charge of the electrochemical apparatus being less than or equal to the state-of-charge threshold, that is, after step iii-2, the intermittent charging operation can be performed on the electrochemical apparatus again, data related to the electrochemical apparatus is obtained in the intermittent charging operation, and the lithium-precipitation state of charge of the electrochemical apparatus is determined based on the data related to the electrochemical apparatus, thus determining the value relationship between the lithium-precipitation state of charge of the electrochemical apparatus and the state-of-charge threshold and then performing step iii-1 or iii-2. In step iii-1, the second charge-discharge cycle can be performed on the electrochemical apparatus at the charging current, thus extending the service life of the electrochemical apparatus; and in step iii-2, the second charge-discharge cycle can be performed on the electrochemical apparatus at a target charging current less than the charging current, thus reducing the risk of lithium precipitation caused by the electrochemical apparatus continuing to operate at the original larger charging current.

The intermittent charging operation may refer to a process of intermittently charging the electrochemical apparatus. In an embodiment of this application, the intermittent charging operation includes multiple charging periods and multiple interruption periods, and the lithium-precipitation state of charge of the electrochemical apparatus is determined in the following manner.

Step A: In the process of the intermittent charging operation, for each of the multiple interruption periods, obtain a state of charge of the electrochemical apparatus and an internal resistance of the electrochemical apparatus that are corresponding to the interruption period.

Step B: Obtain a first curve based on the obtained multiple states of charge of the electrochemical apparatus and the multiple internal resistances of the electrochemical apparatus corresponding to the multiple states of charge.

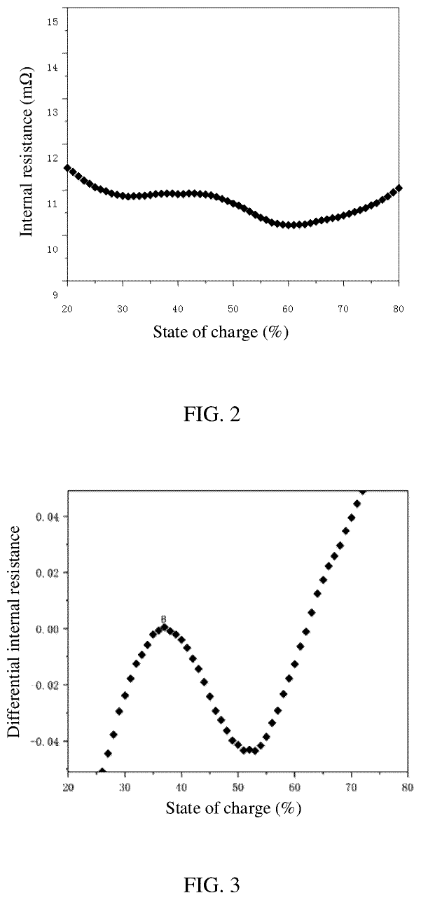

In some embodiments of this application, after the states of charge and internal resistances of the electrochemical apparatus that are corresponding to multiple interruption periods, multiple data pairs composed of state of charge and internal resistance can be obtained. Referring to FIG. 2, with the states of charge of the electrochemical apparatus as horizontal coordinates and the internal resistances of the electrochemical apparatus as vertical coordinates, points represented by these data pairs can be filled in the coordinate system to obtain a first curve through fitting. The first curve represents a mapping curve corresponding to the states of charge and internal resistances of the electrochemical apparatus.

It can be understood that when the state of charge and internal resistance data of the electrochemical apparatus are collected more densely, more data pairs are obtained, and a more detailed first curve can be obtained. The process of curve fitting using data is well known to those skilled in the art and is not specifically limited in some embodiments of this application.

Step C: Determine the lithium-precipitation state of charge of the electrochemical apparatus based on the first curve.

The first curve is a curve representing a mapping relationship between the states of charge and internal resistances of the electrochemical apparatus, and the lithium-precipitation state of charge of the electrochemical apparatus can be determined based on the first curve.

The lithium-precipitation state of charge may not be measured in real time, but is found based on the charging voltage obtained in intermittent charging operation and the correspondence table between charging voltages and states of charge. The correspondence table may be stored in advance in a storage medium of the battery management system, electrochemical apparatus, or electronic device.

In an embodiment, the process of determining the lithium-precipitation state of charge of the electrochemical apparatus based on the first curve may be method 1. Method 1 includes the following steps.

a: Perform a first-order differential on the first curve to obtain a second curve.

As shown in FIG. 3, a second curve is obtained after a first-order differential is performed on the first curve, where the second curve represents the rate of change of the internal resistance of the electrochemical apparatus with the state of charge.

b: Determine, as the lithium-precipitation state of charge, a state of charge corresponding to a point at which the second curve first has a negative slope.

The second curve represents the rate of change of internal resistance with the state of charge. When the rate of change does not show an abnormal decrease in the flat region of the curve, it indicates no active lithium precipitates. When the rate of change shows an abnormal decrease in the flat region of the curve, active lithium precipitates on the surface of the negative electrode and comes into contact with the negative electrode, which is equivalent to the graphite part of the negative electrode being connected in parallel with a lithium metal device, causing the impedance of the entire negative electrode to decrease. As a result, the impedance of the electrochemical apparatus decreases abnormally upon precipitation of active lithium, and correspondingly, the flat region of the second curve shows an abnormal decrease. Referring to FIG. 3, point B is a point at which the second curve first has a negative slope, that is, the flat region of the second curve shows an abnormal decrease for the first time at point B, indicating that the electrochemical apparatus has a tendency of lithium precipitation or has already experienced lithium precipitation at point B. In this case, a state of charge corresponding to point B can be determined as the lithium-precipitation state of charge, so that timely protection is implemented for the electrochemical apparatus based on the value relationship between the lithium-precipitation state of charge and the state-of-charge threshold, improving the use safety of the electrochemical apparatus. The above steps a to b are only used to explain the sequence of steps, but not to limit the sequence of steps.

In an embodiment, the process of determining the lithium-precipitation state of charge of the electrochemical apparatus based on the first curve may be method 2. Method 2 includes the following steps.

a′: Perform a first-order differential on the first curve to obtain a second curve.

This step is the same as step a of method 1, and will not be repeated herein.

b′: Perform a second-order differential on the second curve to obtain a third curve.

A second-order differential may be performed on the second curve to obtain the third curve. It can be understood that the third curve is a second-order differential curve of the second curve.

c′: Determine, as the lithium-precipitation state of charge, a state of charge corresponding to a point at which the third curve first has a vertical coordinate less than zero.

If the third curve has a vertical coordinate less than zero, a state of charge corresponding to a point at which the third curve first has a vertical coordinate less than zero is determined as the lithium-precipitation state of charge.

In an embodiment, the electrochemical apparatus management method according to some embodiments of this application may further include:
determining the target charging current based on a pre-established mapping relationship between charging currents and lithium-precipitation states of charge and at least one of the charging current or the state-of-charge threshold.

The mapping relationship between charging currents and lithium-precipitation states of charge includes at least one charging current and at least one lithium-precipitation state of charge corresponding to the at least one charging current. Referring to Table 1, Table 1 is an established mapping relationship between charging currents and lithium-precipitation states of charge in some embodiments of this application. This table records multiple charging currents and lithium-precipitation states of charge corresponding to the charging currents.

TABLE 1

| | |
|---|---|
| Charging | Lithium-precipitation |
| current (rate) | state of charge |

| | | |
|---|---|---|
| 2.5 | C | 30% |
| 2.4 | C | 35% |
| 2.3 | C | 38% |
| 2.2 | C | 42% |
| 2.1 | C | 46% |
| 2 | C | 49% |
| 1.9 | C | 51% |
| 1.8 | C | 53% |
| 1.7 | C | 56% |
| 1.6 | C | 61% |
| 1.5 | C | 66% |
| 1.4 | C | 68% |
| 1.3 | C | 70% |
| 1.2 | C | 76% |
| 1.1 | C | 78% |
| 1 | C | 81% |

As can be seen from Table 1, multiple charging currents gradually decrease from top to bottom, and lithium-precipitation states of charge corresponding to the charging currents gradually increase. Since the charging current of the electrochemical apparatus is proportional to the charging rate when the capacity of the electrochemical apparatus is constant, for ease of calculation, the charging current is represented by the charging rate in Table 1, where 1 C (rate)=charging current corresponding to capacity of the electrochemical apparatus. The interval value of the foregoing charging currents can be set according to actual needs, and is not particularly limited in some embodiments of this application. Correspondingly, the interval value of the lithium-precipitation states of charge is smaller.

In an optional embodiment of this application, the step of determining the target charging current based on a pre-established mapping relationship between charging currents and lithium-precipitation states of charge and at least one of the charging current or the state-of-charge threshold includes:
determining, as the target charging current, a charging current value in the mapping relationship closest to the charging current.

For example, if the charging current for the first charge-discharge cycle is 2.4 C, it can be seen from Table 1 that the charging current value closest to 2.4 C and less than 2.4 C is 2.3, so the charging current of 2.3 C can be determined as the target charging current.

In another optional embodiment of this application, the step of determining the target charging current based on a pre-established mapping relationship between charging currents and lithium-precipitation states of charge and at least one of the charging current or the state-of-charge threshold includes:
determining, as a target lithium-precipitation state of charge, a lithium-precipitation state of charge in the mapping relationship that is greater than the state-of-charge threshold and has a smallest difference with the state-of-charge threshold, and determining, as the target charging current, a charging current corresponding to the target lithium-precipitation state.

In some embodiments, the target lithium-precipitation state of charge can be determined through comparison between the lithium-precipitation states of charge in Table 1 and the state-of-charge thresholds, so as to determine the target charging current. For example, if the state-of-charge threshold is 49%, a lithium-precipitation state of charge that is greater than 49% and has a smallest difference with 49% is found in Table 1, which is 51%. Then 51% is taken as the target lithium-precipitation state of charge, and the charging current corresponding to 51%, that is, 1.9 C, is the target charging current.

According to some embodiments of this application, the target charging current is determined based on the mapping relationship between charging currents and lithium-precipitation states of charge, which can reduce the charging current of the electrochemical apparatus to the target charging current to reduce the risk of lithium precipitation, improving the safety of the electrochemical apparatus.

In another embodiment, the electrochemical apparatus management method according to some embodiments of this application may further include:
determining the target charging current based on a current ambient temperature, a pre-established mapping relationship between temperatures, charging currents, and lithium-precipitation states of charge, and at least one of the charging current or the state-of-charge threshold, where
the mapping relationship between temperatures, charging currents, and lithium-precipitation states of charge includes at least one ambient temperature, at least one charging current, and at least one lithium-precipitation state of charge corresponding to the at least one charging current. Referring to Table 2, Table 2 is an established mapping relationship between temperatures, charging currents and lithium-precipitation states of charge at different ambient temperatures in some embodiments of this application. This table records at least one ambient temperature, such as 5° C., 25° C., or 45° C., as well as charging currents corresponding to the ambient temperature, and lithium-precipitation states of charge corresponding to the charging currents.

TABLE 2

| | | | Lithium- | | | | Lithium- | | | | Lithium- |
|---|---|---|---|---|---|---|---|---|---|---|---|
| | Charging | | precipitation | | Charging | | precipitation | | Charging | | precipitation |
| | current | | state of | | current | | state of | | current | | state of |
| Temperature | (rate) | | charge | Temperature | (rate) | | charge | Temperature | (rate) | | charge |
| 25° C. | 2.5 | C | 30% | 45° C. | 2.5 | C | 40% | 5° C. | 1.5 | C | 40% |
| 25° C. | 2.4 | C | 35% | 45° C. | 2.4 | C | 43% | 5° C. | 1.4 | C | 47% |
| 25° C. | 2.3 | C | 38% | 45° C. | 2.3 | C | 45% | 5° C. | 1.3 | C | 50% |
| 25° C. | 2.2 | C | 42% | 45° C. | 2.2 | C | 51% | 5° C. | 1.2 | C | 55% |
| 25° C. | 2.1 | C | 46% | 45° C. | 2.1 | C | 55% | 5° C. | 1.1 | C | 58% |
| 25° C. | 2 | C | 49% | 45° C. | 2 | C | 58% | 5° C. | 1 | C | 64% |
| 25° C. | 1.9 | C | 51% | 45° C. | 1.9 | C | 60% | 5° C. | 0.9 | C | 70% |
| 25° C. | 1.8 | C | 53% | 45° C. | 1.8 | C | 63% | 5° C. | 0.8 | C | 73% |
| 25° C. | 1.7 | C | 56% | 45° C. | 1.7 | C | 68% | 5° C. | 0.7 | C | 75% |
| 25° C. | 1.6 | C | 61% | 45° C. | 1.6 | C | 70% | 5° C. | 0.6 | C | 79% |
| 25° C. | 1.5 | C | 66% | 45° C. | 1.5 | C | 73% | 5° C. | 0.5 | C | 83% |

| | | | | | | | | | | |
|---|---|---|---|---|---|---|---|---|---|---|
| 25° C. | 1.4 | C | 68% | 45° C. | 1.4 | C | 76% | / | / | / |
| 25° C. | 1.3 | C | 70% | 45° C. | 1.3 | C | 80% | / | / | / |
| 25° C. | 1.2 | C | 76% | 45° C. | 1.2 | C | 83% | / | / | / |
| 25° C. | 1.1 | C | 78% | 45° C. | 1.1 | C | 88% | / | / | / |
| 25° C. | 1 | C | 81% | 45° C. | 1 | C | 90% | / | / | / |

In Table 2, “/” indicates no corresponding value.

As can be seen from Table 2, at the same temperature, multiple charging currents gradually decrease from top to bottom, and lithium-precipitation states of charge corresponding to the charging currents gradually increase. The electrochemical apparatus can operate at different ambient temperatures. Based on this, Table 2 of some embodiments of this application records a correspondence between the charging currents and lithium-precipitation states of charge of the electrochemical apparatus when the electrochemical apparatus operates at different ambient temperatures.

Table 1 and Table 2 can be stored as data in a storage medium, for example, a storage medium of the battery management system, a storage medium of the electrochemical apparatus, or a storage medium of the electronic device, and a processor of the battery management system/electrochemical apparatus/electronic device can read the mapping relationship data stored in the storage medium.

In an optional embodiment of this application, the step of determining the target charging current based on a current ambient temperature, a pre-established mapping relationship between charging currents and lithium-precipitation states of charge, and at least one of the charging current or the state-of-charge threshold includes:
at the current ambient temperature, determining, as the target charging current, a charging current value in the mapping relationship closest to the charging current.

For example, the current operating environment temperature of the electrochemical apparatus is 25° C., and if the charging current for the first charge-discharge cycle is 2.4 C, it can be seen from Table 2 that the charging current value closest to 2.4 C and less than 2.4 C is 2.3, so the charging current of 2.3 C can be determined as the target charging current, that is, the target charging current of the electrochemical apparatus at an ambient temperature of 25° C. is 2.3 C.

In another optional embodiment of this application, the step of determining the target charging current based on a current ambient temperature, a pre-established mapping relationship between charging currents and lithium-precipitation states of charge, and at least one of the charging current or the state-of-charge threshold includes:
at the current ambient temperature, determining, as a target lithium-precipitation state of charge, a lithium-precipitation state of charge in the mapping relationship that is greater than the state-of-charge threshold and has a smallest difference with the state-of-charge threshold, and determining, as the target charging current, a charging current corresponding to the target lithium-precipitation state.

For example, if the current operating environment temperature of the electrochemical apparatus is 25° C. and the state-of-charge threshold is 49%, a lithium-precipitation state of charge that is greater than 49% and has a smallest difference with 49% is found from the data column 25° C. in Table 2, which is 51%. Then 51% is taken as the target lithium-precipitation state of charge, and the charging current corresponding to 51%, namely 1.9 C, is the target charging current, that is, the target charging current of the electrochemical apparatus at an ambient temperature of 25° C. is 1.9 C.

According to some embodiments of this application, the target charging current is determined based on the mapping relationship between temperatures, charging currents, and lithium-precipitation states of charge, which can reduce the charging currents of the electrochemical apparatus at different ambient temperatures to the target charging current to reduce the risk of lithium precipitation, improving the safety of the electrochemical apparatus operating at different ambient temperatures.

In an embodiment of this application, the intermittent charging operation can be performed on the electrochemical apparatus again after the charging current is reduced and a second number of cycles are completed. When the lithium-precipitation state of charge of the electrochemical apparatus is less than the state-of-charge threshold, the current reduction operation is performed again based on the charging current shown in Table 1 or Table 2 until the charging current is reduced to the minimum current in Table 1 or Table 2, and then the electrochemical apparatus is controlled to stop operating, thus further improving the safety of the electrochemical apparatus.

In an embodiment, the intermittent charging operation may include multiple charging cycles, each charging cycle includes a charging period and an interruption period, and during each charging period, the state of charge of the electrochemical apparatus increases by a unit amplitude, that is, the state of charge of the electrochemical device is increased by a certain amplitude during each charging period, for example, by 0.5% SOC, 1% SOC, 5% SOC or 10% SOC during each charging period.

In some embodiments of this application, the intermittent charging operation includes multiple charging cycles, and each charging cycle includes one charging period and one interruption period. For example, a first charging period and a first interruption period form a first charging cycle, a second charging period and a second interruption period form a second charging cycle, a third charging period and a third interruption period form a third charging cycle, and so on. It can be understood that one charging cycle is a continuous period of time.

For example, the electrochemical apparatus is charged during the first charging period, then the charging is stopped, and after the first interruption period, the electrochemical apparatus is charged again during the second charging period. Such process is repeated until the state of charge of the electrochemical apparatus reaches a first critical value. It can be understood that as the intermittent charging proceeds, the state of charge of the electrochemical apparatus increases. In some embodiments of this application, the intermittent charging can be stopped when the state of charge of the electrochemical apparatus reaches the first critical value, so as to complete the intermittent charging operation. The first critical value is not particularly limited in some embodiments of this application, provided that the objectives of this application can be achieved. For example, the first critical value may be 60%, 70%, 80%, 90%, or 100%.

In the process of the intermittent charging operation, the unit amplitude of the states of charge corresponding to different charging cycles may be different. For example, the electrochemical apparatus is charged during the first charging period, and after the state of charge of the electrochemical apparatus increases by 1%, the charging is stopped; after an interval of 5 seconds, the electrochemical apparatus is charged during the second charging period, and after the state of charge of the electrochemical apparatus increases by 5%, the charging is stopped; after an interval of 5 seconds, the electrochemical apparatus is charged during the third charging period, and after the state of charge of the electrochemical apparatus increases by 3%, the charging is stopped; and so on. Such process is repeated until the state of charge of the electrochemical apparatus reaches a first threshold.

In an embodiment, the intermittent charging operation may specifically be: for any one of the multiple charging cycles, charging the electrochemical apparatus at a first moment, and stopping the charging after the state of charge of the electrochemical apparatus increases by a unit amplitude, where the charging is stopped at a second moment, charging is not started until a third moment, and a time interval between the third moment and the second moment is duration of the interruption period. During the interruption period, the electrochemical apparatus may be in a state of not being charged or discharged, that is, a state of standing.

For example, the electrochemical apparatus starts being charged at moment T₁, and the charging is stopped after the state of charge of the electrochemical apparatus increases by a unit amplitude, where a moment when the charging is stopped is moment T₂; and the electrochemical apparatus is left standing from moment T₂, and a moment when the standing ends is moment T₃.

According to some embodiments of this application, the intermittent charging operation is performed on the electrochemical apparatus, the data related to the electrochemical apparatus can be obtained during the intermittent charging operation, and the lithium-precipitation state of charge of the electrochemical apparatus can be determined based on such data, so as to perform the step of continuing the cycle at the original charging current or at a reduced current, thus helping to reduce the risk of lithium precipitation of the electrochemical apparatus and extending the service life of the electrochemical apparatus.

The electrochemical apparatus management method according to some embodiments of this application includes at least one of lithium iron phosphate system electrochemical apparatus, lithium nickel cobalt manganate system electrochemical apparatus, or lithium cobalt oxide system electrochemical apparatus. Normally, in the intermittent charging operation, electrochemical apparatuses of different systems correspond to different unit amplitudes and different interruption period durations. Based on this:
in an embodiment, the electrochemical apparatus is a lithium iron phosphate system electrochemical apparatus, the unit amplitude ranges from 0.5% to 10%, and duration of the interruption period ranges from 1 second to 15 seconds.

In an embodiment, the electrochemical apparatus is a lithium nickel cobalt manganate system electrochemical apparatus, the unit amplitude ranges from 0.5% to 10%, and duration of the interruption period ranges from 1 second to 30 seconds.

In an embodiment, the electrochemical apparatus is a lithium cobalt oxide system electrochemical apparatus, the unit amplitude ranges from 0.5% to 10%, and duration of the interruption period ranges from 1 second to 30 seconds.

According to some embodiments of this application, different unit amplitudes and different interruption period durations are set for electrochemical apparatuses of different systems, so that the intermittent charging operation is performed more targetedly on the electrochemical apparatuses of different systems, and the lithium-precipitation states of charge of the electrochemical apparatuses of different systems can be obtained more accurately.

Normally, in the intermittent charging operation, electrochemical apparatuses of a same system correspond to different unit amplitudes and different interruption period durations under different temperature conditions. Based on this:
in an embodiment, the electrochemical apparatus is a lithium iron phosphate system electrochemical apparatus, the electrochemical apparatus is at an ambient temperature of −10° C. to 10° C., the unit amplitude ranges from 0.5% to 10%, and duration of the interruption period ranges from 5 second to 15 seconds. In an embodiment, the electrochemical apparatus is a lithium iron phosphate system electrochemical apparatus, the electrochemical apparatus is at an ambient temperature of 10° C. to 45° C., the unit amplitude ranges from 0.5% to 10%, and duration of the interruption period ranges from 1 second to 10 seconds.

In some embodiments of this application, a positive electrode of the lithium iron phosphate system electrochemical apparatus may also include other positive electrode active materials, but lithium iron phosphate is the main material. For example, lithium iron phosphate accounts for any one of 51%, 60%, 70%, 80%, 90%, and 98% of total mass of the positive electrode active materials.

In an embodiment, the electrochemical apparatus is a lithium nickel cobalt manganate system electrochemical apparatus, the electrochemical apparatus is at an ambient temperature of −10° C. to 10° C., the unit amplitude ranges from 0.5% to 10%, and duration of the interruption period ranges from 10 second to 30 seconds. In an embodiment, the electrochemical apparatus is a lithium nickel cobalt manganate system electrochemical apparatus, the electrochemical apparatus is at an ambient temperature of 10° C. to 45° C., the unit amplitude ranges from 0.5% to 10%, and duration of the interruption period ranges from 1 second to 10 seconds.

In some embodiments of this application, a positive electrode of the lithium nickel cobalt manganate system electrochemical apparatus may also include other positive electrode active materials, but lithium nickel cobalt manganate is the main material. For example, lithium nickel cobalt manganate accounts for any one of 51%, 60%, 70%, 80%, 90%, and 98% of total mass of the positive electrode active materials.

In an embodiment, the electrochemical apparatus is a lithium cobalt oxide system electrochemical apparatus, the electrochemical apparatus is at an ambient temperature of −10° C. to 10° C., the unit amplitude ranges from 0.5% to 10%, and duration of the interruption period ranges from 15 second to 30 seconds. In an embodiment, the electrochemical apparatus is a lithium cobalt oxide system electrochemical apparatus, the electrochemical apparatus is at an ambient temperature of 10° C. to 45° C., the unit amplitude ranges from 0.5% to 10%, and duration of the interruption period ranges from 1 second to 10 seconds.

In some embodiments of this application, a positive electrode of the lithium cobalt oxide system electrochemical apparatus may also include other positive electrode active materials, but lithium cobalt oxide is the main material. For example, lithium cobalt oxide accounts for any one of 51%, 60%, 70%, 80%, 90%, and 98% of total mass of the positive electrode active materials.

According to some embodiments of this application, different unit amplitudes and different interruption period durations are set for electrochemical apparatuses of a same system at different temperatures, so that the intermittent charging operation is performed more targetedly on the electrochemical apparatuses in different temperature environments, and the lithium-precipitation states of charge of the electrochemical apparatuses of different systems can be obtained more accurately.

The state-of-charge threshold may refer to a state of charge corresponding to occurrence of lithium precipitation in the electrochemical apparatus, and is typically related to the system of the electrochemical apparatus. In some embodiments of this application, the state-of-charge threshold can be set according to actual needs, and the state-of-charge threshold can be different based on characteristics of electrochemical apparatuses of different systems. For example, the electrochemical apparatus is a lithium iron phosphate system electrochemical apparatus, and the state-of-charge threshold ranges from 30% to 70%, for example, 30%, 40%, 50%, 60%, or 70%; the electrochemical apparatus is a lithium nickel cobalt manganate system electrochemical apparatus, and the state-of-charge threshold ranges from 20% to 50%, for example, 20%, 30%, 40%; or 50%; the electrochemical apparatus is a lithium cobalt oxide system electrochemical apparatus, and the state-of-charge threshold ranges from 20% to 50%, for example, 20%, 30%, 40%, or 50%.

Different state-of-charge thresholds are set for electrochemical apparatuses of different systems, so that management policies of electrochemical apparatuses of different systems can be optimized more targetedly, extending the safety use time of the electrochemical apparatuses of different systems.

In an embodiment, generating a first curve includes the following steps.

Step a: Obtain a first voltage, a first current, and a first state of charge of the electrochemical apparatus at the second moment, and a second voltage and a second current of the electrochemical apparatus at the third moment.

The second moment is a moment when charging is stopped. A voltage, a current, and a state of charge of the electrochemical apparatus at the second moment, that is, the first voltage, the first current, and the first state of charge, can be obtained and denoted as V₁, I₁, and SOC₁, respectively. Similarly, a voltage and a current of the electrochemical apparatus at the third moment, that is, the second voltage and the second current, can be obtained and denoted as V₂ and I₂, respectively.

Step b: Calculate a voltage change value and a current change value of the electrochemical apparatus that are corresponding to the interruption period.

The duration of the interruption period is the time interval between the third moment and the second moment; the voltage change value of the electrochemical apparatus during the interruption period are ΔV, where ΔV=V₂−V₁; and the current change value of the electrochemical apparatus corresponding to the interruption period are ΔI, where ΔI=I₂−I₁.

Step c: Calculate a first internal resistance of the electrochemical apparatus corresponding to the interruption period based on the voltage change value and the current change value, and use the first internal resistance and the first state of charge as one of the data pairs of the first curve, where the data pair is a correspondence between internal resistance and state of charge.

The first internal resistance of the electrochemical apparatus corresponding to the interruption period is R₁, where R₁=ΔV/ΔI. R₁ and SOC₁ are used as one of the data pairs of the first curve. According to the foregoing method, multiple data pairs can be obtained.

Step d: Generate the first curve based on the multiple data pairs obtained.

With the states of charge of the electrochemical apparatus as horizontal coordinates and the internal resistances of the electrochemical apparatus as vertical coordinates, points represented by these data pairs are filled in the coordinate system to obtain the first curve through fitting. According to some embodiments of this application, after the first curve is obtained, the lithium-precipitation state of charge of the electrochemical apparatus can be determined through the first curve, so that the step of performing a cycle on the electrochemical apparatus based still on the original charging current or based on a reduced current is performed based on a value relationship between the lithium-precipitation state of charge and the state-of-charge threshold, helping to reduce the risk of lithium precipitation of the electrochemical apparatus and extending the service life of the electrochemical apparatus.

According to the electrochemical apparatus management method in some embodiments of this application, the lithium-precipitation state of charge of the electrochemical apparatus is determined based on the data related to the electrochemical apparatus obtained in the intermittent charging operation, and in response to the lithium-precipitation state of charge of the electrochemical apparatus being less than or equal to the state-of-charge threshold, the electrochemical apparatus is charged at a smaller charging current, namely the target charging current. This can reduce the charging current of the electrochemical apparatus to reduce the risk of lithium precipitation, improving the safety of the electrochemical apparatus.

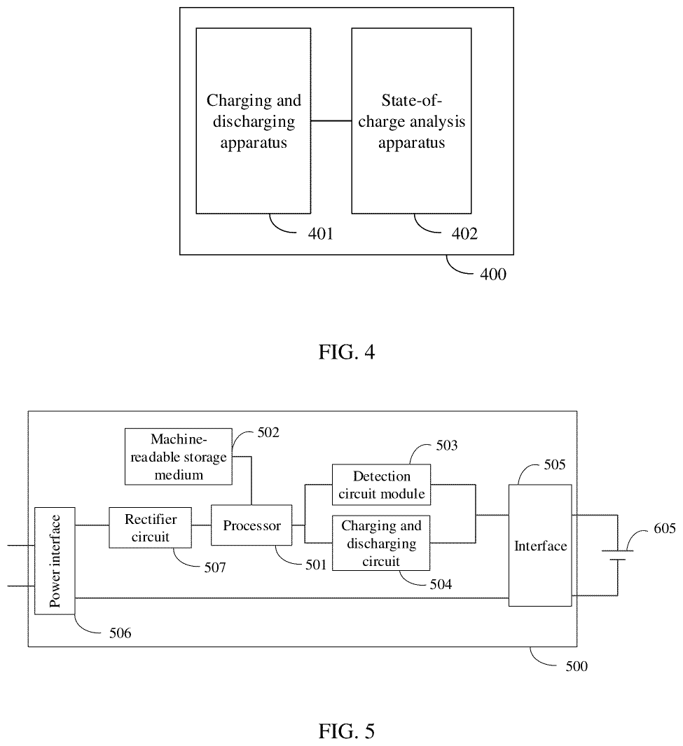

An embodiment of this application further provides a system 400, where the system may include a battery management system. As shown in FIG. 4, the system 400 includes a charging and discharging apparatus 401 and a state-of-charge analysis apparatus 402.

The charging and discharging apparatus 401 is configured to perform a first charge-discharge cycle on an electrochemical apparatus at a charging current.

The state-of-charge analysis apparatus 402 is configured to perform an intermittent charging operation on the electrochemical apparatus at a detection current, obtain data related to the electrochemical apparatus in the intermittent charging operation, and determine a lithium-precipitation state of charge of the electrochemical apparatus based on the data related to the electrochemical apparatus.

The charging and discharging apparatus 401 is further configured to: in response to the lithium-precipitation state of charge of the electrochemical apparatus being greater than a state-of-charge threshold, perform a second charge-discharge cycle on the electrochemical apparatus at the charging current; or in response to the lithium-precipitation state of charge of the electrochemical apparatus being less than or equal to a state-of-charge threshold, performing a second charge-discharge cycle on the electrochemical apparatus at a target charging current, where the target charging current is less than the charging current.

Structures of the charging and discharging apparatus 401 and the state-of-charge analysis apparatus 402 are not particularly limited in some embodiments of this application, provided that the corresponding functions can be implemented.

In an embodiment, the intermittent charging operation includes multiple charging periods and multiple interruption periods, and the state-of-charge analysis apparatus is specifically configured to:
in the intermittent charging operation, for each of the multiple interruption periods, obtain a state of charge of the electrochemical apparatus and an internal resistance of the electrochemical apparatus that are corresponding to the interruption periods, and obtain a first curve based on the obtained multiple states of charge of the electrochemical apparatus and the multiple internal resistances of the electrochemical apparatus corresponding to the multiple states of charge, where the first curve is a mapping curve corresponding to the states of charge and internal resistances of the electrochemical apparatus; and determine the lithium-precipitation state of charge of the electrochemical apparatus based on the first curve.

In an embodiment, the state-of-charge analysis apparatus is specifically configured to:
perform a first-order differential on the first curve to obtain a second curve; and determine, as the lithium-precipitation state of charge, a state of charge corresponding to a point at which the second curve first has a negative slope; where it can be understood that the point at which the second curve first has a negative slope can be determined using a technique known to those skilled in the art, which is not limited in this application; for example, this application uses the following method to test the point where at which the second curve first has a negative slope: calculating a slope based on data points corresponding to every two adjacent states of charge; and recording the obtained points at which the slope first appears as negative as point 1 and point 2, where the point with a larger state of charge between point 1 and point 2 is the point at which the second curve first has a negative slope;
or
perform a first-order differential on the first curve to obtain a second curve; perform a second-order differential on the second curve to obtain a third curve; and determine, as the lithium-precipitation state of charge, a state of charge corresponding to a point at which the third curve first has a vertical coordinate less than zero.

In an embodiment, the charging and discharging apparatus is further configured to:
determine the target charging current based on a pre-established mapping relationship between charging currents and lithium-precipitation states of charge and at least one of the charging current or the state-of-charge threshold, where the mapping relationship between charging currents and lithium-precipitation states of charge includes at least one charging current and at least one lithium-precipitation state of charge corresponding to the at least one charging current.

In an embodiment, the charging and discharging apparatus is specifically configured to:
determine, as the target charging current, a charging current value in the mapping relationship closest to the charging current; or
determine, as a target lithium-precipitation state of charge, a lithium-precipitation state of charge in the mapping relationship that is greater than the state-of-charge threshold and has a smallest difference with the state-of-charge threshold, and determine, as the target charging current, a charging current corresponding to the target lithium-precipitation state.

In an embodiment, the charging and discharging apparatus is further configured to:
determine the target charging current based on a current ambient temperature, a pre-established mapping relationship between temperatures, charging currents, and lithium-precipitation states of charge, and at least one of the charging current or the state-of-charge threshold, where the mapping relationship between temperatures, charging currents, and lithium-precipitation states of charge includes at least one ambient temperature, at least one charging current, and at least one lithium-precipitation state of charge corresponding to the at least one charging current.

In an embodiment, the charging and discharging apparatus is specifically configured to:
at the current ambient temperature, determine, as the target charging current, a charging current value in the mapping relationship closest to the charging current; or
at the current ambient temperature, determine, as a target lithium-precipitation state of charge, a lithium-precipitation state of charge in the mapping relationship that is greater than the state-of-charge threshold and has a smallest difference with the state-of-charge threshold, and determine, as the target charging current, a charging current corresponding to the target lithium-precipitation state.

In an embodiment, the intermittent charging operation includes multiple charging cycles, each charging cycle includes a charging period and an interruption period, and during each charging period, the state of charge of the electrochemical apparatus increases by a unit amplitude.

In an embodiment, the electrochemical apparatus includes at least one of lithium iron phosphate system electrochemical apparatus, lithium nickel cobalt manganate system electrochemical apparatus, or lithium cobalt oxide system electrochemical apparatus:
in a case that the electrochemical apparatus is a lithium iron phosphate system electrochemical apparatus, the unit amplitude ranges from 0.5% to 10%, and duration of the interruption period ranges from 1 second to 15 seconds;
in a case that the electrochemical apparatus is a lithium nickel cobalt manganate system electrochemical apparatus, the unit amplitude ranges from 0.5% to 10%, and duration of the interruption period ranges from 1 second to 30 seconds; and
in a case that the electrochemical apparatus is a lithium cobalt oxide system electrochemical apparatus, the unit amplitude ranges from 0.5% to 10%, and duration of the interruption period ranges from 1 second to 30 seconds.

In an embodiment, the state-of-charge analysis apparatus is specifically configured for at least one of the following (a) to (f):
(a) the electrochemical apparatus is a lithium iron phosphate system electrochemical apparatus, the electrochemical apparatus is at an ambient temperature of −10° C. to 10° C., the unit amplitude ranges from 0.5% to 10%, and duration of the interruption period ranges from 5 second to 15 seconds;
(b) the electrochemical apparatus is a lithium iron phosphate system electrochemical apparatus, the electrochemical apparatus is at an ambient temperature of 10° C. to 45° C., the unit amplitude ranges from 0.5% to 10%, and duration of the interruption period ranges from 1 second to 10 seconds;
(c) the electrochemical apparatus is a lithium nickel cobalt manganate system electrochemical apparatus, the electrochemical apparatus is at an ambient temperature of −10° C. to 10° C., the unit amplitude ranges from 0.5% to 10%, and duration of the interruption period ranges from 10 second to 30 seconds;
(d) the electrochemical apparatus is a lithium nickel cobalt manganate system electrochemical apparatus, the electrochemical apparatus is at an ambient temperature of 10° C. to 45° C., the unit amplitude ranges from 0.5% to 10%, and duration of the interruption period ranges from 1 second to 10 seconds;
(e) the electrochemical apparatus is a lithium cobalt oxide system electrochemical apparatus, the electrochemical apparatus is at an ambient temperature of −10° C. to 10° C., the unit amplitude ranges from 0.5% to 10%, and duration of the interruption period ranges from 15 second to 30 seconds; or
(f) the electrochemical apparatus is a lithium cobalt oxide system electrochemical apparatus, the electrochemical apparatus is at an ambient temperature of 10° C. to 45° C., the unit amplitude ranges from 0.5% to 10%, and duration of the interruption period ranges from 1 second to 10 seconds.

In the system according to some embodiments of this application, the state-of-charge analysis apparatus is configured to: perform an intermittent charging operation on the electrochemical apparatus, obtain data related to the electrochemical apparatus in the intermittent charging operation, and determine a lithium-precipitation state of charge of the electrochemical apparatus based on the data related to the electrochemical apparatus; and when the lithium-precipitation state of charge of the electrochemical apparatus is less than or equal to a state-of-charge threshold, charge the electrochemical apparatus at a smaller charging current, namely a target charging current. This can reduce the charging current of the electrochemical apparatus to reduce the risk of lithium precipitation, improving the safety of the electrochemical apparatus.

An embodiment of this application further provides a charging apparatus. As shown in FIG. 5, the charging apparatus 500 includes a processor 501 and a machine-readable storage medium 502. The charging apparatus 500 may further include a detection circuit module 503, a charging and discharging circuit 504, an interface 505, a power interface 506, and a rectifier circuit 507. The detection circuit module 503 is configured to perform an intermittent charging operation on a lithium-ion battery 605 to detect a lithium-precipitation state of charge of the lithium-ion battery, and send a detection result to the processor 501. The charging and discharging circuit 504 is configured to receive an instruction from the processor 501, and perform a charging or discharging operation on the lithium-ion battery 605. The interface 505 is configured to be electrically connected to the lithium-ion battery 605. The power interface 506 is configured to be connected to an external power source. The rectifier circuit 507 is configured to rectify an input current. The machine-readable storage medium 502 stores machine-executable instructions capable of being executed by the processor. When the processor 501 executes the machine-executable instructions, the steps of the method described in any one of the foregoing embodiments are implemented.

An embodiment of this application further provides a computer-readable storage medium. The computer-readable storage medium stores a computer program, and when the computer program is executed by a processor, the steps of the method according to any one of the foregoing embodiments are implemented.

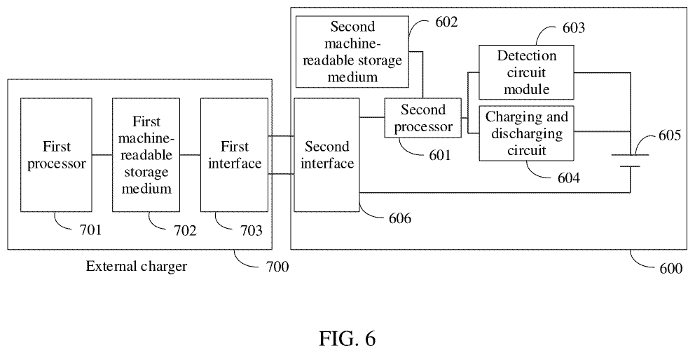

An embodiment of this application further provides a system. As shown in FIG. 6, the system 600 includes a second processor 601 and a second machine-readable storage medium 602. The system 600 may further include a detection circuit module 603, a charging and discharging circuit 604, a lithium-ion battery 605, and a second interface 606. The detection circuit module 603 is configured to perform an intermittent charging operation on the lithium-ion battery 605 to detect a lithium-precipitation state of charge of the lithium-ion battery 605, and send a detection result to the second processor 601. The charging and discharging circuit 604 is configured to receive an instruction from the second processor 601, and perform a charging or discharging operation on the lithium-ion battery 605. The second interface 606 is configured to be electrically connected to an interface of an external charger 700. The external charger 700 is configured to supply power. The second machine-readable storage medium 602 stores machine-executable instructions capable of being executed by the processor. When the second processor 601 executes the machine-executable instructions, the steps of the method described in any one of the foregoing embodiments are implemented. The external charger 700 may include a first processor 701, a first machine-readable storage medium 702, a first interface 703, and a corresponding rectifier circuit. The external charger may be a commercially available charger, and its structure is not specifically limited in some embodiments of this application.

An embodiment of this application further provides an electronic device including the electrochemical apparatus according to the following embodiments. The electronic device in the embodiment of this application may include an electrochemical apparatus. For example, the electronic device can be a device having a built-in lithium-ion battery and data processing capability, such as a mobile phone or a tablet computer.

A machine-readable storage medium may include a random access memory (Random Access Memory, RAM for short), or may include a non-volatile memory (non-volatile memory), for example, at least one disk memory. Optionally, the memory may alternatively be at least one storage apparatus located far away from the processor.

The processor may be a general purpose processor, including a central processing unit (Central Processing Unit, CPU for short), a network processor (Network Processor, NP for short), or the like; or may be a digital signal processor (Digital Signal Processing, DSP for short), an application-specific integrated circuit (Application-Specific Integrated Circuit, ASIC for short), a field-programmable gate array (Field-Programmable Gate Array, FPGA for short) or another programmable logic device, a discrete gate or transistor logic device, or a discrete hardware component.

It should be noted that relational terms such as “first” and “second” are only used to distinguish one entity or operation from another entity or operation, and do not necessarily require or imply that there is any such actual relationship or order between these entities or operations. Terms “comprise”, “include”, or any other variations thereof are intended to cover non-exclusive inclusions, such that a process, method, article or device including a series of elements not only includes these elements, but also includes other elements which are not expressly listed, or further includes elements which are inherent to such process, method, article or device.

The embodiments in this specification are described in a related manner. For a part that is the same or similar between the embodiments, reference may be made between the embodiments. Each embodiment focuses on differences from other embodiments.

The system/electronic device/charging apparatus/storage medium embodiment is essentially similar to the method embodiment, and therefore is described briefly. For related information, refer to descriptions of the related parts in the method embodiment.

The foregoing descriptions are merely preferred embodiments of this application, but are not intended to limit this application. Any modification, equivalent replacement, or improvement made without departing from the spirit and principle of this application shall fall within the protection scope of this application.

What is claimed is:

1. An electrochemical apparatus management method, wherein the method comprises:
i. performing a first charge-discharge cycle on an electrochemical apparatus at a charging current;
ii. performing an intermittent charging operation on the electrochemical apparatus at a detection current, obtaining data related to the electrochemical apparatus in the intermittent charging operation, and determining a lithium-precipitation state of charge of the electrochemical apparatus based on the data related to the electrochemical apparatus; and
iii-1. in response to the lithium-precipitation state of charge of the electrochemical apparatus being greater than a state-of-charge threshold, performing a second charge-discharge cycle on the electrochemical apparatus at the charging current,
or
iii-2. in response to the lithium-precipitation state of charge of the electrochemical apparatus being less than or equal to a state-of-charge threshold, performing a second charge-discharge cycle on the electrochemical apparatus at a target charging current, wherein the target charging current is less than the charging current.

2. The electrochemical apparatus management method according to claim 1, further comprising:
after step iii-1, repeating step ii and step iii-1 or iii-2; or
after step iii-2, repeating step ii and step iii-1 or iii-2.

3. The electrochemical apparatus management method according to claim 1, wherein the data related to the electrochemical apparatus comprises a state of charge of the electrochemical apparatus and an internal resistance of the electrochemical apparatus; the intermittent charging operation comprises multiple charging periods and multiple interruption periods; and the step of obtaining data related to the electrochemical apparatus in the intermittent charging operation, and determining a lithium-precipitation state of charge of the electrochemical apparatus based on the data related to the electrochemical apparatus, comprises:
in the intermittent charging operation, for each of the multiple interruption periods, obtaining a state of charge of the electrochemical apparatus and an internal resistance of the electrochemical apparatus that are corresponding to the interruption period;
obtaining a first curve based on the obtained multiple states of charge of the electrochemical apparatus and the multiple internal resistances of the electrochemical apparatus corresponding to the multiple states of charge, wherein the first curve is a mapping curve corresponding to the states of charge and internal resistances of the electrochemical apparatus; and
determining the lithium-precipitation state of charge of the electrochemical apparatus based on the first curve.

4. The electrochemical apparatus management method according to claim 3, wherein the step of determining the lithium-precipitation state of charge of the electrochemical apparatus based on the first curve comprises at least one of method 1 or method 2, wherein
method 1 comprises:
performing a first-order differential on the first curve to obtain a second curve; and
determining, as the lithium-precipitation state of charge, a state of charge corresponding to a point at which the second curve first has a negative slope;
method 2 comprises:
performing a first-order differential on the first curve to obtain a second curve;
performing a second-order differential on the second curve to obtain a third curve; and
determining, as the lithium-precipitation state of charge, a state of charge corresponding to a point at which the third curve first has a vertical coordinate less than zero.

5. The electrochemical apparatus management method according to claim 1, further comprising:
determining the target charging current based on a pre-established mapping relationship between charging currents and lithium-precipitation states of charge and at least one of the charging current or the state-of-charge threshold, wherein the mapping relationship between charging currents and lithium-precipitation states of charge comprises at least one charging current and at least one lithium-precipitation state of charge corresponding to the at least one charging current.

6. The electrochemical apparatus management method according to claim 5, wherein the determining the target charging current based on a pre-established mapping relationship between charging currents and lithium-precipitation states of charge and at least one of the charging current or the state-of-charge threshold comprises:
determining, as the target charging current, a charging current value in the mapping relationship closest to the charging current; or
determining, as a target lithium-precipitation state of charge, a lithium-precipitation state of charge in the mapping relationship that is greater than the state-of-charge threshold and has a smallest difference with the state-of-charge threshold, and determining, as the target charging current, a charging current corresponding to the target lithium-precipitation state.

7. The electrochemical apparatus management method according to claim 1, further comprising:
determining the target charging current based on a current ambient temperature, a pre-established mapping relationship between temperatures, charging currents, and lithium-precipitation states of charge, and at least one of the charging current or the state-of-charge threshold; wherein the mapping relationship between temperatures, charging currents, and lithium-precipitation states of charge comprises at least one ambient temperature, at least one charging current, and at least one lithium-precipitation state of charge corresponding to the at least one charging current.

8. The electrochemical apparatus management method according to claim 7, wherein the determining the target charging current based on a current ambient temperature, a pre-established mapping relationship between temperatures, charging currents and lithium-precipitation states of charge, and at least one of the charging current or the state-of-charge threshold comprises:
at the current ambient temperature, determining, as the target charging current, a charging current value in the mapping relationship closest to the charging current; or
at the current ambient temperature, determining, as a target lithium-precipitation state of charge, a lithium-precipitation state of charge in the mapping relationship that is greater than the state-of-charge threshold and has a smallest difference with the state-of-charge threshold, and determining, as the target charging current, a charging current corresponding to the target lithium-precipitation state.

9. The electrochemical apparatus management method according to claim 1, wherein the intermittent charging operation comprises multiple charging cycles, each charging cycle comprises a charging period and an interruption period, and during each charging period, the state of charge of the electrochemical apparatus increases by a unit amplitude.

10. The electrochemical apparatus management method according to claim 9, wherein the electrochemical apparatus comprises at least one of a lithium iron phosphate system electrochemical apparatus, a lithium nickel cobalt manganate system electrochemical apparatus, or a lithium cobalt oxide system electrochemical apparatus, wherein
in a case that the electrochemical apparatus is the lithium iron phosphate system electrochemical apparatus, the unit amplitude ranges from 0.5% to 10%, and a duration of the interruption period ranges from 1 second to 15 seconds;
in a case that the electrochemical apparatus is the lithium nickel cobalt manganate system electrochemical apparatus, the unit amplitude ranges from 0.5% to 10%, and the duration of the interruption period ranges from 1 second to 30 seconds; and
in a case that the electrochemical apparatus is the lithium cobalt oxide system electrochemical apparatus, the unit amplitude ranges from 0.5% to 10%, and the duration of the interruption period ranges from 1 second to 30 seconds.

11. The electrochemical apparatus management method according to claim 9, wherein the method satisfies at least one of conditions (a) to (f):
(a) the electrochemical apparatus is the lithium iron phosphate system electrochemical apparatus, the electrochemical apparatus is at an ambient temperature of −10° C. to 10° C., the unit amplitude ranges from 0.5% to 10%, and the duration of the interruption period ranges from 5 second to 15 seconds;
(b) the electrochemical apparatus is the lithium iron phosphate system electrochemical apparatus, the electrochemical apparatus is at an ambient temperature of 10° C. to 45° C., the unit amplitude ranges from 0.5% to 10%, and the duration of the interruption period ranges from 1 second to 10 seconds;
(c) the electrochemical apparatus is the lithium nickel cobalt manganate system electrochemical apparatus, the electrochemical apparatus is at an ambient temperature of −10° C. to 10° C., the unit amplitude ranges from 0.5% to 10%, and the duration of the interruption period ranges from 10 second to 30 seconds;
(d) the electrochemical apparatus is the lithium nickel cobalt manganate system electrochemical apparatus, the electrochemical apparatus is at an ambient temperature of 10° C. to 45° C., the unit amplitude ranges from 0.5% to 10%, and the duration of the interruption period ranges from 1 second to 10 seconds;
(e) the electrochemical apparatus is the lithium cobalt oxide system electrochemical apparatus, the electrochemical apparatus is at an ambient temperature of −10° C. to 10° C., the unit amplitude ranges from 0.5% to 10%, and the duration of the interruption period ranges from 15 second to 30 seconds; or
(f) the electrochemical apparatus is the lithium cobalt oxide system electrochemical apparatus, the electrochemical apparatus is at an ambient temperature of 10° C. to 45° C., the unit amplitude ranges from 0.5% to 10%, and the duration of the interruption period ranges from 1 second to 10 seconds.

12. A charging apparatus, comprising a processor and a machine-readable storage medium, wherein the machine-readable storage medium stores machine-executable instructions capable of being executed by the processor, and when the processor executes the machine-executable instructions to implement an electrochemical apparatus management method, wherein the method comprises:
i. performing a first charge-discharge cycle on an electrochemical apparatus at a charging current;
ii. performing an intermittent charging operation on the electrochemical apparatus at a detection current, obtaining data related to the electrochemical apparatus in the intermittent charging operation, and determining a lithium-precipitation state of charge of the electrochemical apparatus based on the data related to the electrochemical apparatus; and
iii-1. in response to the lithium-precipitation state of charge of the electrochemical apparatus being greater than a state-of-charge threshold, performing a second charge-discharge cycle on the electrochemical apparatus at the charging current,
or
iii-2. in response to the lithium-precipitation state of charge of the electrochemical apparatus being less than or equal to a state-of-charge threshold, performing a second charge-discharge cycle on the electrochemical apparatus at a target charging current, wherein the target charging current is less than the charging current.

13. A system, comprising a charging and discharging apparatus and a state-of-charge analysis apparatus, wherein
the charging and discharging apparatus is configured to perform a first charge-discharge cycle on an electrochemical apparatus at a charging current;
the state-of-charge analysis apparatus is configured to perform an intermittent charging operation on the electrochemical apparatus at a detection current, obtain data related to the electrochemical apparatus in the intermittent charging operation, and determine a lithium-precipitation state of charge of the electrochemical apparatus based on the data related to the electrochemical apparatus; and
the charging and discharging apparatus is further configured to: in response to the lithium-precipitation state of charge of the electrochemical apparatus being greater than a state-of-charge threshold, perform a second charge-discharge cycle on the electrochemical apparatus at the charging current;
or
in response to the lithium-precipitation state of charge of the electrochemical apparatus being less than or equal to a state-of-charge threshold, perform a second charge-discharge cycle on the electrochemical apparatus at a target charging current, wherein the target charging current is less than the charging current.

14. The system according to claim 13, wherein the data related to the electrochemical apparatus comprises a state of charge of the electrochemical apparatus and an internal resistance of the electrochemical apparatus; the intermittent charging operation comprises multiple charging periods and multiple interruption periods; and the state-of-charge analysis apparatus is specifically configured to:
in the intermittent charging operation, for each of the multiple interruption periods, obtain a state of charge of the electrochemical apparatus and an internal resistance of the electrochemical apparatus that are corresponding to the interruption periods, and obtain a first curve based on the obtained multiple states of charge of the electrochemical apparatus and the multiple internal resistances of the electrochemical apparatus corresponding to the multiple states of charge, wherein the first curve is a mapping curve corresponding to the states of charge and internal resistances of the electrochemical apparatus; and
determine the lithium-precipitation state of charge of the electrochemical apparatus based on the first curve.

15. The system according to claim 14, wherein the state-of-charge analysis apparatus is specifically configured to:
perform a first-order differential on the first curve to obtain a second curve; and
determine, as the lithium-precipitation state of charge, a state of charge corresponding to a point at which the second curve first has a negative slope;
or
perform a first-order differential on the first curve to obtain a second curve;
perform a second-order differential on the second curve to obtain a third curve; and
determine, as the lithium-precipitation state of charge, a state of charge corresponding to a point at which the third curve first has a vertical coordinate less than zero.

16. The system according to claim 13, wherein the charging and discharging apparatus is further configured to:
determine the target charging current based on a pre-established mapping relationship between charging currents and lithium-precipitation states of charge and at least one of the charging current or the state-of-charge threshold, wherein the mapping relationship between charging currents and lithium-precipitation states of charge comprises at least one charging current and at least one lithium-precipitation state of charge corresponding to the at least one charging current.

17. The system according to claim 16, wherein the charging and discharging apparatus is specifically configured to:
determine, as the target charging current, a charging current value in the mapping relationship closest to the charging current; or
determine, as a target lithium-precipitation state of charge, a lithium-precipitation state of charge in the mapping relationship that is greater than the state-of-charge threshold and has a smallest difference with the state-of-charge threshold, and determine, as the target charging current, a charging current corresponding to the target lithium-precipitation state.

18. The system according to claim 13, wherein the charging and discharging apparatus is further configured to:
determine the target charging current based on a current ambient temperature, a pre-established mapping relationship between temperatures, charging currents, and lithium-precipitation states of charge, and at least one of the charging current or the state-of-charge threshold, wherein the mapping relationship between temperatures, charging currents, and lithium-precipitation states of charge comprises at least one ambient temperature, charging current, and at least one lithium-precipitation state of charge corresponding to the at least one charging current.

19. The system according to claim 18, wherein the charging and discharging apparatus is specifically configured to:
at the current ambient temperature, determine, as the target charging current, a charging current value in the mapping relationship closest to the charging current; or
at the current ambient temperature, determine, as a target lithium-precipitation state of charge, a lithium-precipitation state of charge in the mapping relationship that is greater than the state-of-charge threshold and has a smallest difference with the state-of-charge threshold, and determine, as the target charging current, a charging current corresponding to the target lithium-precipitation state.

20. The system according to claim 13, wherein the intermittent charging operation comprises multiple charging cycles, each charging cycle comprises a charging period and an interruption period, and during each charging period, the state of charge of the electrochemical apparatus increases by a unit amplitude.
